(19) United States
(12) Patent Application Publication
(10) Pub. No.: US 2008/0169951 A1
(43) Pub. Date: Jul. 17, 2008

(54) Direct digital synthesis of transmitter gain and bias control curves

(75) Inventors: Ivan Krivokapic, San Diego, CA (US); Lun Bin Huan, San Diego, CA (US)

Correspondence Address: STMICROELECTRONICS, INC., MAIL STATION 2346, 1310 ELECTRONICS DRIVE, CARROLLTON, TX, 75006, US

(73) Assignee: STMicroelectronics, Inc., Carrollton, TX (US)

(21) Appl. No.: 11/654,330

(22) Filed: Jan. 17, 2007

(51) Int. Cl. H03M 1/00

(52) U.S. Cl. 341/139

(57) ABSTRACT

A transmitter includes a plurality of devices which processes a transmit signal. Examples of such devices include a variable gain amplifier, a power amplifier and/or a modulator. Some other these devices are gain controllable. Some of these devices are bias controllable. Each controllable device receives at least one analog control signal (gain/bias) which sets operation of the controllable device. A logic circuit receives a specification of the analog control signal and generating a digital control signal based thereon. A digital-to-analog converter circuit converts the digital control signal to the analog control signal for application to the controllable device. The digital control signal generated by the logic circuit comprises a plurality of connected linear segments (a digital piecewise approximation) which approximate the specification of the analog (gain/bias) control signal, and the generated analog control signal is comprised of a corresponding plurality of connected analog linear segments (an analog piecewise approximation).

### BACKGROUND OF THE INVENTION

1. Technical Field of the Invention

The present invention relates to radio frequency transmitters and, more particularly, to the digital generation of bias/gain control curves for the modulator and amplifier circuitry of a radio frequency transmitter.

2. Description of Related Art

Common analog transmitter biasing schemes are prone to variation due to temperature and process variations. Current saving in the transmitter depends on roll-of current steepness versus gain reduction. Achieving stability of the steep roll-off curve is particularly challenging in analog biasing schemes. Furthermore, transmitter system gain stability versus temperature/process in analog control circuits represent a design issue as well.

Achievable current/gain back-off shapes in the analog domain are typically limited by circuit complexity and often represent a compromise between circuit implementation feasibility and transmitter efficiency. Due to temperature/process instabilities, complex optimal and stabile current back-off/gain control schemes that, for example, include current/gain control of the modulator in addition to the Variable Gain Amplifier (VGA) circuit and Pre-Power Amplifier (PPA) circuit, are difficult to implement utilizing purely analog signal generation techniques.

A need exists for an improvement in the generation of bias/gain control curves for the modulator and amplifier circuitry of a radio frequency transmitter

### SUMMARY OF THE INVENTION

The present invention proposes a digital generation of bias/gain control curves. This eliminates stability problems associated with analog signal generation circuit and allows for the generation of arbitrary control functions that are suitable for optimizing transmitter performance. Since control curve parameters are fully programmable in this approach in the digital domain, the solution is quite suitable for complex gain/current control schemes. Pulse Density Modulator (PDM) digital-to-analog converters and their filters are an integral part of the proposed solution.

In accordance with the invention, a direct digital synthesis of bias/gain control curves in an RF transmitter ASIC is provided. This solution provides a simple means of eliminating stability problems and allows for the generation of arbitrary control functions that are suitable for transmitter performance optimization. The parameters defining control curves are fully programmable, and the direct synthesis of such curves offers high flexibility in comparison to an analog circuit implementation, with a corresponding power savings benefit.

In an embodiment, a transmitter comprises a gain controllable device which processes a transmit signal, the gain controllable device receiving an analog gain control signal which sets a gain of the gain controllable device, a logic circuit receiving a specification of the analog gain control signal and generating a digital gain control signal based thereon, and a digital-to-analog converter circuit that converts the digital gain control signal to the analog gain control signal for application to the gain controllable device. The gain controllable device is one of a variable gain amplifier and/or a modulator. The digital gain control signal generated by the logic circuit comprises a plurality of connected linear segments (a digital piecewise approximation) which approximate the specification of the analog gain control signal, and the generated analog gain control signal is comprised of a corresponding plurality of connected analog linear segments (an analog piecewise approximation).

In another embodiment, a transmitter comprises a device which processes a transmit signal and whose bias is controllable, the device receiving an analog bias control signal which sets a bias of the device, a logic circuit receiving a specification of the analog bias control signal and generating a digital bias control signal based thereon, and a digital-to-analog converter circuit that converts the digital bias control signal to the analog bias control signal for application to the device. The device is one of a variable gain amplifier, power amplifier and/or a modulator. The digital bias control signal generated by the logic circuit comprises a plurality of connected linear segments (a digital piecewise approximation) which approximate the specification of the analog bias control signal, and the generated analog bias control signal is comprised of a corresponding plurality of connected analog linear segments (an analog piecewise approximation).

In another embodiment, a transmitter comprises a modulator for modulating a digital baseband signal for RF transmission, the modulator having a controllable bias and receiving an analog bias control signal which sets a bias of the modulator, and an amplifier for amplifying the RF modulated digital baseband signal, the amplifier having a controllable gain and receiving an analog gain control signal which sets a gain of the amplifier. A logic circuit receives a specification of the analog bias control signal and the analog gain control signal, and then generates a digital bias control signal and a digital gain control signal based thereon. A first digital-to-analog converter circuit converts the digital bias control signal to the analog bias control signal for application to the modulator. A second digital-to-analog converter circuit converts the digital gain control signal to the analog gain control signal for application to the amplifier.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 is a block diagram of a radio frequency transmitter including a digital gain/current control circuit;

FIG. 2 is a block diagram of a core logic circuit of the digital gain/current control circuit;

FIG. 3 is an implementation example for a PDM decoder;

FIG. 4 is an output graph representing dynamics of the PDM decoder tracking PDM input register changes versus time;

FIG. 5 is a block diagram illustrating the PDM decoder;

FIG. 6 is a block diagram for RF control register selection;

FIG. 7 is a block diagram of a linear segment approximation parameter super (LSAPS) block;

FIGS. 8-10 are block diagrams of different types of LSAP blocks within the LSAPS block;

FIG. 11 is a synthesis of six segments which are piecewise approximated for a hypothetical control current back-off curve; and

FIG. 12 is a block diagram of a PDM DAC block.

### DETAILED DESCRIPTION OF THE DRAWINGS

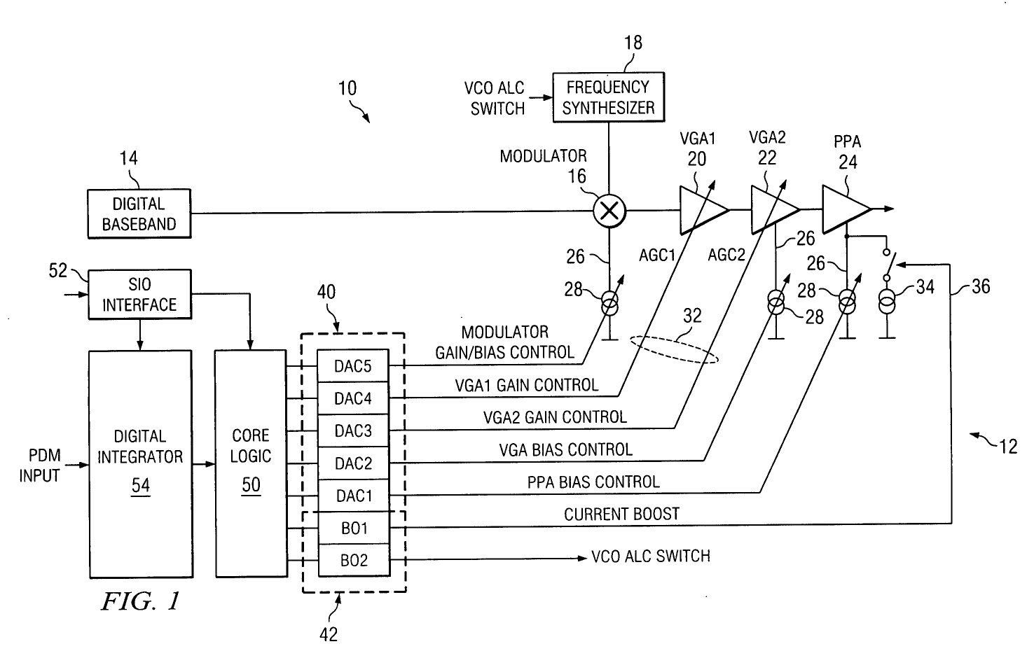

Reference is now made to FIG. 1 wherein there is shown a block diagram of a radio frequency transmitter 10 including a digital gain/current control circuit 12. The transmitter 10 includes a digital baseband circuit 14 having an output applied to the input of a mixer (modulator) 16. Another input of the mixer 16 receives a carrier frequency signal output by a frequency synthesizer 18 whose operation mode is controlled by a received digital Voltage Controlled Oscillator (VCO) Automatic Level Control (ALC) switch signal. An output of the mixer 16 is applied to the input of a first Variable Gain Amplifier (VGA) circuit 20. An output of the first VGA 20 is applied to the input of a second VGA 22. An output of the second VGA 22 is applied to the input of a Pre-Power Amplifier (PPA) circuit 24. An output of the PPA 24 is then passed on for radio frequency transmission.

The mixer 16, second VGA 22 and PPA 24 each include an additional input 26 coupled to a controllable current source 28. Each controllable current source 28 includes a control input 30 receiving an analog bias control signal comprising a control current back-off signal. The received control current back-off signal controls an amount of current passing through the controllable current source 28 so as to adjust operation of the mixer 16, second VGA 22 and/or PPA 24 in a manner known to those skilled in the art. In particular, the analog bias control signal received by the controllable current source 28 associated with the mixer 16 may also effectuate some control over modulator gain in a manner known to those skilled in the art.

The biasing of the PPA 24 and VGA 22 requires a current source. The interface with the bias control inputs allows for voltage to current conversion. This interface is temperature compensated and accepts a 0.1-1.8V control voltage input (where 0.1V corresponds to maximum 100 uA and 1.8V to minimum ˜0 uA biasing current).

The first VGA 20 and second VGA 22 each include an additional input 32 coupled to receive an analog gain control signal. The received gain control signal controls a gain of the first VGA 20 and second VGA 22 in a manner known to those skilled in the art. In order to accommodate an interface with the VGA2/VGA1 blocks, it is necessary to provide a temperature compensated level conversion function separately for VGA 20 and VGA 22. The interface provides temperature compensation for VGA 20/VGA 22 gain variation caused by amplifier currents fluctuations, accepts 0.1-1.8V control voltage input (where 0.1V corresponds to maximum and 1.8V to minimum gain) and provides a linear dB transfer characteristic.

With respect to the PPA 24, a fixed current source 34 is coupled though a switch 36 to an input of the PPA 24. The switch 36 is controlled by a digital current boost signal. The received current boost signal selectively actuates the fixed current source 34 to as to adjust, in cooperation with the controllable current source 28, operation of the PPA 24 in a manner known to those skilled in the art.

A set of digital-to-analog converters 40 are provided to generate the analog bias control signals (control current back-off signals) and analog gain control signals for application to the mixer 16, first VGA 20, second VGA 22 and PPA 24 circuits (collectively as including the associated controllable current sources 28).

A set of digital buffers 42 are provided to generate the digital VCO ALC switch signal and thus increase or decrease VCO level, e.g. decrease or increase phase noise and increase or decrease current consumption, respectively, to the frequency synthesizer 18. The switch 36, serves the purpose of boosting PPA (Pre Power Amplifier) at high power level if necessary.

The digital signals applied to the inputs of the digital-to-analog converters 40 and digital buffers 42 are generated by a core logic circuit 50. With respect to the digital signals applied to the inputs of the digital-to-analog converters 40, these digital signals generated by the core logic circuit 50 comprise digital representations of the analog bias control signals (control current back-off signals) and analog gain control signals for application to the mixer 16, first VGA 20, second VGA 22 and PPA 24 circuits (collectively as including the associated controllable current sources 28). In this way, the shape of the resulting analog signals is defined in the digital domain, and thus can be better controlled in comparison to prior art devices where analog circuitry is used to define the shape of and generate the analog bias control signals (control current back-off signals) and analog gain control signals. With respect to the digital signals applied to the inputs of the digital buffers 42, these digital signals generated by the core logic circuit 50 comprise digital logic control signals which may be the same logic or complementary logic to the digital VCO ALC switch signal and digital current boost signal applied to the frequency synthesizer 18 and switch 36, respectively.

The core logic circuit 50 includes two general inputs. A first input receives signals from a serial input/output (SIO) interface 52. A second input receives signals from a digital integrator circuit 54 (which is part of a PDM decoder block to be described herein). Thus, by this mean, gain control could be achieved trough SIO or PDM interface. The SIO interface 52 further includes an output connected to an input of the digital integrator circuit 54. The SIO interface 52 receives and decodes serially communicated input data. The digital integrator circuit 54 receives pulse density modulator (PDM) input data.

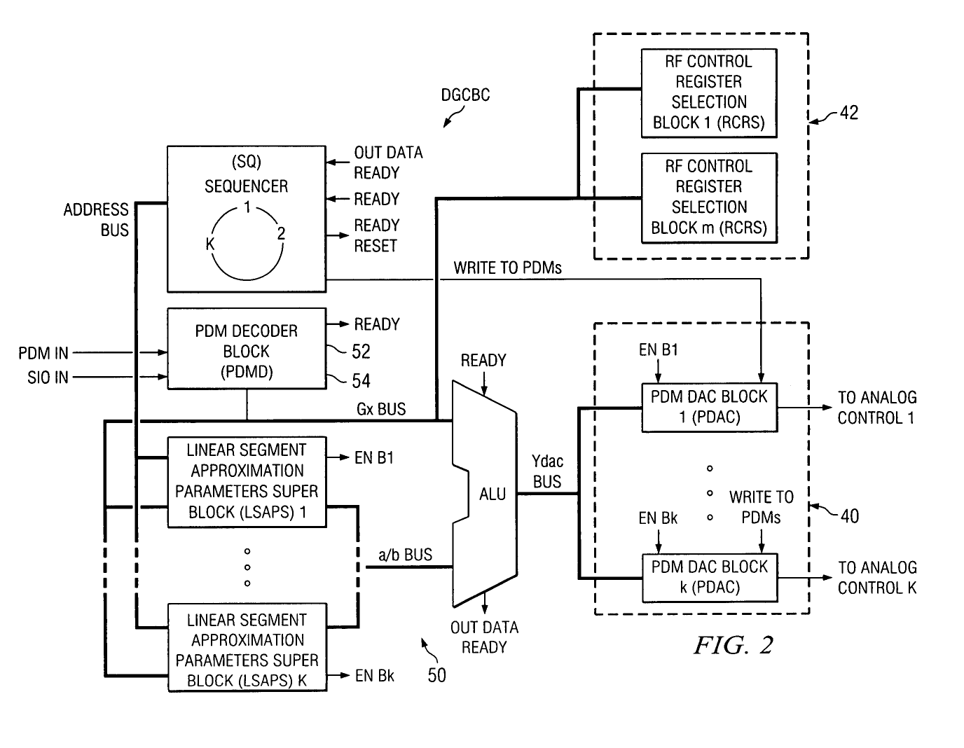

Reference is now made to FIG. 2 wherein there is shown a block diagram of a digital gain and current control back-off control (DGCBC) block which includes the core logic circuit 50 of the digital gain/current control circuit 12 along with the set of digital-to-analog converters 40 and buffers 42. The DGCBC block includes a PDM decoder (PDMD), a set of k linear segment approximation parameter super blocks (LSAPS), an arithmetic logic unit (ALU), a sequencer block (SQ), a set of k PDM DAC (PDAC) blocks which comprise the digital-to-analog converters (DAC) 40, and a set of m RF control register selection blocks (RCRS) which comprise the digital buffers 42. Each of PDM DAC (PDAC) blocks includes a buffer register, converter and filter to be discussed in more detail herein (see FIG. 12). As mentioned previously, a SIO interface 52 is provided (see, FIG. 1) to facilitate programming of the DGCBC block. An address bus interconnects the sequencer block (SQ) and the set of k linear segment approximation parameter super blocks (LSAPS).

Operation of the DGCBC block of FIG. 2 is as follows: the PDMD converts a received PDM sequence (comprising a digital version of the desired bias control signals (control current back-off signals) and/or analog gain control signals) into a 10 bit wide binary value that is output on the Gx bus. At the same time, the PDMD generates a READY signal which is applied to the sequencer block (SQ). The sequencer block (SQ) responds thereto by sequentially activating appropriate blocks of the set of k LSAPS blocks through the address bus (appropriate in this case referring the to the LSAPS block corresponding to the PDAC which will be generating the analog signal). Each LSAPS block can generate an enable (EN) signal which is used to enable a corresponding block in the set of k PDM DAC (PDAC) blocks comprising the digital-to-analog converters (DAC) 40. More specifically, the enable (EN) signal enables the buffer within the corresponding PDAC block so that the PDAC block will receive digital data to be converted to an analog signal output. The binary value present on the Gx bus is analyzed in the LSAPS block which was activated by the sequencer block (SQ). The activated LSAPS block the generates, from the binary value present on the Gx bus, corresponding linear segment “a” and “b” parameters which are output on the a/b bus. These parameters digitally define the characteristics of the desired analog bias/gain signal. The a/b bus is applied to one input of the ALU. The ALU includes a second input connected to the Gx bus. The ALU, responsive to receipt of the READY signal, performs a multiplication and subtraction operation with respect to the “a” and “b” parameters present on the a/b bus and the binary value present on the Gx bus. More specifically, the mathematical operation performed by the ALU is (equation 1):

Ydac=bᵢ−aᵢGx

wherein i=1, 2, . . . , n, with, for example, nₘₐₓ=6. The output Ydac from the ALU is applied to a Ydac bus connected to the set of k PDM DAC (PDAC) blocks comprising the digital-to-analog converters (DAC) 40. The Ydac data output is loaded into the buffer within the PDAC block which is being activated by the enable (EN) signal which is output from the corresponding LSAPS block activated by the sequencer block (SQ). The sequencer block (SQ) causes the foregoing process to be sequentially repeated, loading Ydac data into a PDAC buffer corresponding to the selected LSAPS, until the last (i.e., the k-th) PDAC buffer has been loaded. At that point, the sequence has reached its end and the ALU generates and activates an OUT DATA READY signal. The OUT DATA READY signal is applied to an input of the sequencer block (SQ) causing the sequencer block (SQ) to reset and generate a WRITE TO PDM signal which is applied to set of k PDM DAC (PDAC) blocks. The set of k PDM DAC (PDAC) blocks responds to the received WRITE TO PDM signal by transferring (latching) the data stored in the buffer to the DAC so as to generate to an appropriate analog output signal from the DAC circuit. Upon receipt of a next (new) active READY signal from the PDMD block, the foregoing process repeats and generates a next analog signal value from the set of k PDM DAC (PDAC) blocks.

The set of m RSCR blocks are asynchronously operated. In other words, their operation is not scheduled by the sequencer block (SQ) as is true with respect to the set of k linear segment approximation parameter super (LSAPS) blocks and the set of k PDM DAC (PDAC) blocks. The RSCR blocks serve as the digital buffers 42 (see, FIG. 1) connected to the Gx bus. Each block represents a digital comparator that functions to switch RF control registers storing digital control bits for setting power amplifier driver current (through the switch 36) or PLL VCO control (of the frequency synthesizer 18) based on the Gx bus value output by the PDPM.

The PDMD block includes the digital integrator circuit 54 and SIO interface 52. The PDMD block receives baseband PDM data serially at a PDM input and performs a PDM decoding (digital integration) on the received data. The counting (integration time) is determined as (equation 2):

$${T}_{d int} = \frac{{2}^{n}}{{f}_{sclk}}$$

wherein n is the number of PDM bit resolution, and f_{sclk} is the sampling frequency. In this particular case, the PDM resolution is preferably 10 bits and f_{sclk}=19.2 MHz. Therefore, T_{d int}=53.3 us and the counting clock period is 106.6 us.

With reference again to FIG. 1, it will be noted that the serial input/output (SIO) interface 52 provides an alternative input for gain control data. In this case, using the serial input bus and the SIO interface, the gain control data can be input to the DGCBC block and in this mode the connection from the SIO interface to the PDMD block (including the digital integrator circuit 54) enables operation of the PDM processing portion of the PDMD block to be disabled. Thus, the input gain control data is instead routed by the PDMD block directly from SIO bus to the Gx bus of the DGCBC block.

The following specifications are applicable to the PDMD block: 1) support 19.2 or 9.6 MHz PDM update frequencies; 2) incorporate an input PDM data/clock synchronization mechanism (in case the baseband clock and the PDM decoder clock phases are not aligned, even if derived from a common frequency reference); 3) incorporate an enable/disable option so that AGC control data can be routed directly from the SIO bus; 4) generate the READY signal when current register output content is different from previously loaded register content; 5) the READY RESET input signal resets ready state; and 6) ensure transparency with respect to PDM input access to the core logic.

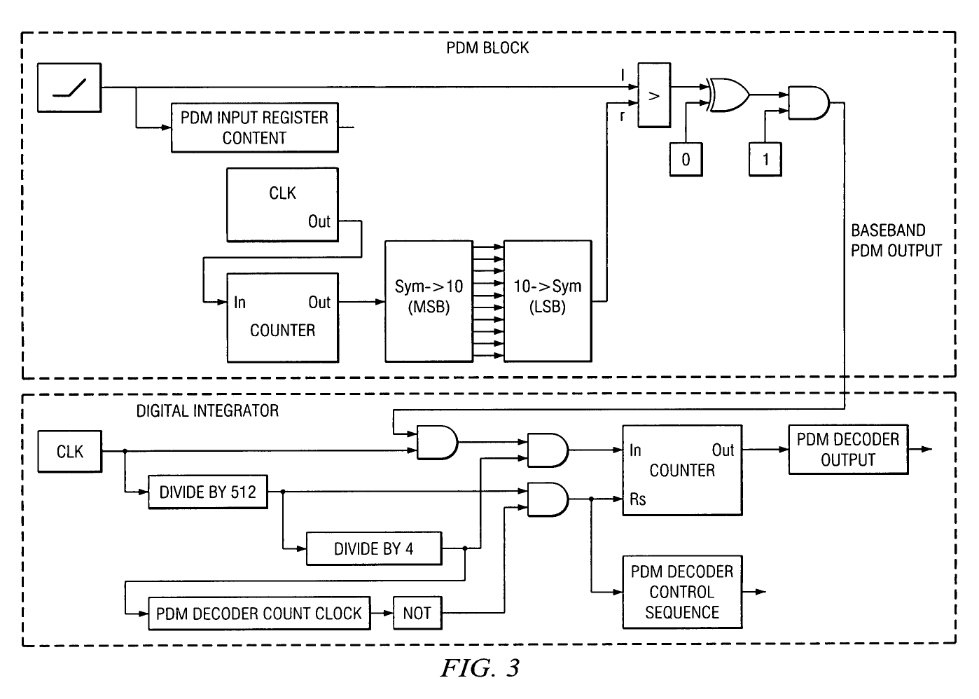

Reference is now made to FIG. 3 wherein there is shown an implementation example for a PDM decoder. The pulse density modulator (PDM) block receives a PDM signal. Pulse density modulation is a form of modulation to represent an analog signal in the digital domain. In a PDM signal, the relative density of the pulses corresponds to an amplitude of the analog signal. The simplicity of PDM makes it a suitable modulation scheme choice where multiple analog levels need to be supported. The operation of PDM is well known to those skilled in the art. Basically, PDM systems use a clock, counter, bit reversion block (MSB->LSB), and a comparator. The bit reversion block receives the output of the counter which is driven by the clock. The output of the bit reversion block is compared by the comparator against a register value representing the PDM rate (the PDM input register content). If the PDM rate register content is higher then the bit reverted counter binary word (the output of the bit reversion block), then the comparator generates a logic “1” output. Otherwise, the comparator generates a logic “0” output. The comparator output can be selectively inverted by the XOR function (so as to support changes in curve sign enabling the generation of both monotonically rising and monotonically declining curves). An AND gate receives an enable signal dictating whether baseband PDM output is to be supplied. In order to meet necessary accuracy requirements, it is preferable to use 10 bit resolution for PDM. The baseband PDM output, if enabled for output, is then processed in a PDM decoder/digital integrator circuit (of any suitable design well known to those skilled in the art) to produce a serial data signal which may be stored in a register (and output on the Gx bus) for further processing as will be discussed further herein.

More particularly, FIG. 3 depicts one possible implementation of a digital to analog converter (DAC) and in this case this case the DAC is a so called pulse density modulator. The purpose of this block is to convert a digital signal into an analog signal, thus interfacing a digital part of the system to the actual analog block. In another words, actual bias and gain settings are calculated by the digital state machine and those values are passed to the analog block of the transmitter. Examples of such values comprises values for the amplifier bias control and gain control of the variable gain amplifier.

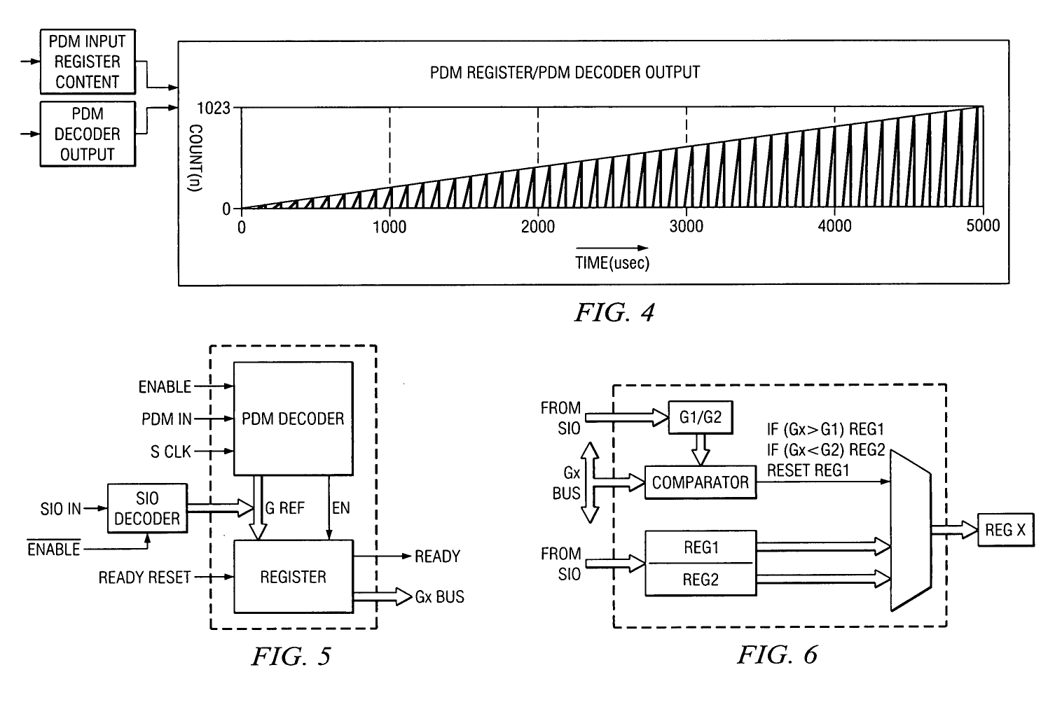

Reference is now made to FIG. 4 wherein there is shown an output graph representing dynamics of the PDM decoder tracking PDM input register changes versus time. This graph represents an example of the PDM encoder/decoder operation. The sloped line on the graph from count(n) 0 to 1023 represents the changing numeric value periodically loaded into an encoder PDM register periodically by a numeric ramp generator (small block in upper left corner of FIG. 3). Therefore, there is a respectively changing PDM sequence at the baseband output. This is important because a cell phone digital baseband chip produces this PDM sequence for the purpose of gain control in the RF transmitter ASIC. A typical analog implementation passes this sequence through a simple resistive/capacitive block in order to generate an analog control signal proportional to the PDM duty cycle sequence. In accordance with the present invention, however, instead of using an analog approach a digital integrator or PDM decoder is provided and incorporated on the TX ASIC side. The decoder actually counts pulses generated by the PDM within a predefined time frame (integration time). The process of counting within this time frame is shown by the triangular (sawtooth) waveform on the graph. It will be noted from the graph that the peak of each of these triangles corresponds to the appropriate value of the ramp. This indicates that the decoder correctly decoded the numeric value loaded into the PDM encoder. After termination of the counting process, the counted value is loaded in an appropriate register for further processing and the counter is cleared (see, each vertical line on each triangle or sawtooth) and is ready for next counting process.

Reference is now made to FIG. 5 wherein there is shown a block diagram illustrating the PDM decoder block. The PDM decoder (PDMD) block includes a PDM decoder which includes an enable input, a serial automatic gain control (AGC) data input for PDM IN signal input, and a clock input. The PDM decoder operates to decode the received PDM data input (if enabled) and output decoded data on the G ref bus for storage in a register (REG). The PDM decoder further generates an enable (EN) output which is applied to the register. The SIO decoder is connected to receive data (such as AGC data for SIO IN) from a serial input bus. The SIO decoder also receives an enable input. The SIO decoder functions to decode the received data input (if enabled) and output decoded SIO data on the G ref bus for storage in the register (REG). This allows AGC data to be input through the SIO decoder thus bypassing the PDM decoder. The register receives a READY RESET signal and responds thereto by resetting a READY signal output. The READY signal output is generated when the register currently stores content different from previously loaded content. The parallel data output of the register is connected to the Gx bus.

Reference is now made to FIG. 6 wherein there is shown a block diagram for RF control register selection. The RSCR blocks serve as the digital buffers 42 (see, FIGS. 1 and 2). In order to introduce current savings, two different automatic levels of control in the synthesizer VCO shall be generated in RF Control Register Selection Block (RCRS). The RSCR block incorporates switching with hysteresis with respect to the two different automatic levels of control. In another role the RSCR block is used for driver amplifier current boost (see switch 36) for the purpose of reducing second harmonic level and thus injection pulling effects in the PPA circuit in the frequency plans where VCO frequency is the same or integer number times higher than transmitter output frequency. The driver amplifier current boost thus is used to reduce, for example, harmonic content level in the frequency plans where VCO frequency is integer number higher then output TX frequency, thus reducing injection pulling effects.

In this case the RSCR block is a simple programmable switch that alters states of the VCO (Voltage Control Oscillator) register at the certain transmitter gain level, thus changing reducing or increasing the VCO signal level. Reduced VCO level leads to reduced current consumption, but this make VCO more susceptible to the injection pulling. This effect occurs when output signal of the transmitter or it harmonic being coupled to the VCO that frequency is directly or harmonically related to transmitter frequency. Result of this effect is degradation of VCO phase noise performances and this degradation is proportional to the TX power level and inversely proportional to the VCO signal level. Therefore at high gain (TX output power level e.g. harmonic level) the idea is to increase VCO signal level in order to minimize pulling and at the certain point of gain to reduce it level when TX output power (harmonic level) is sufficiently low not to cause pulling problems.

As shown in FIGS. 2 and 6, the RSCR blocks are connected to the Gx bus. Through communications over the Gx bus, the RSCR blocks receive gain values which originate at either the PDM input or the SIO input. Each RSCR block operates to compare gain value currently being received on the Gx bus against preprogrammed reference gain values G1 and G2 which were programmed into associated 10-bit registers G1 and G2 through the SIO input. These reference gain values are the determining point of whether the content of registers REG1 or REG2 get loaded into output register REG X. The REG1 and REG2 values can also be loaded through the SIO input. In one implementation, REG X is a VCO ALC register in the frequency synthesizer 18, and thus REG1 and REG2 comprise two bit registers containing VCO ALC bit settings defining operation parameters of the frequency synthesizer 18. In another implementation, REG X is a current boost register associated with the switch 36, and thus REG1 and REG2 comprise two bit registers containing boost settings defining operation parameters of the PPA.

The comparison operation compares the current gain value on the Gx bus against the previously stored G1 value. If Gx>G1, then the RSCR block selects the contents of REG1 for output to REG X. The comparison operation further compares the current gain value on the Gx bus against the previously stored G2 value. If Gx<G2, then the RSCR block selects the contents of REG2 for output to REG X. The difference in G1 and G2 values defines the hysteresis.

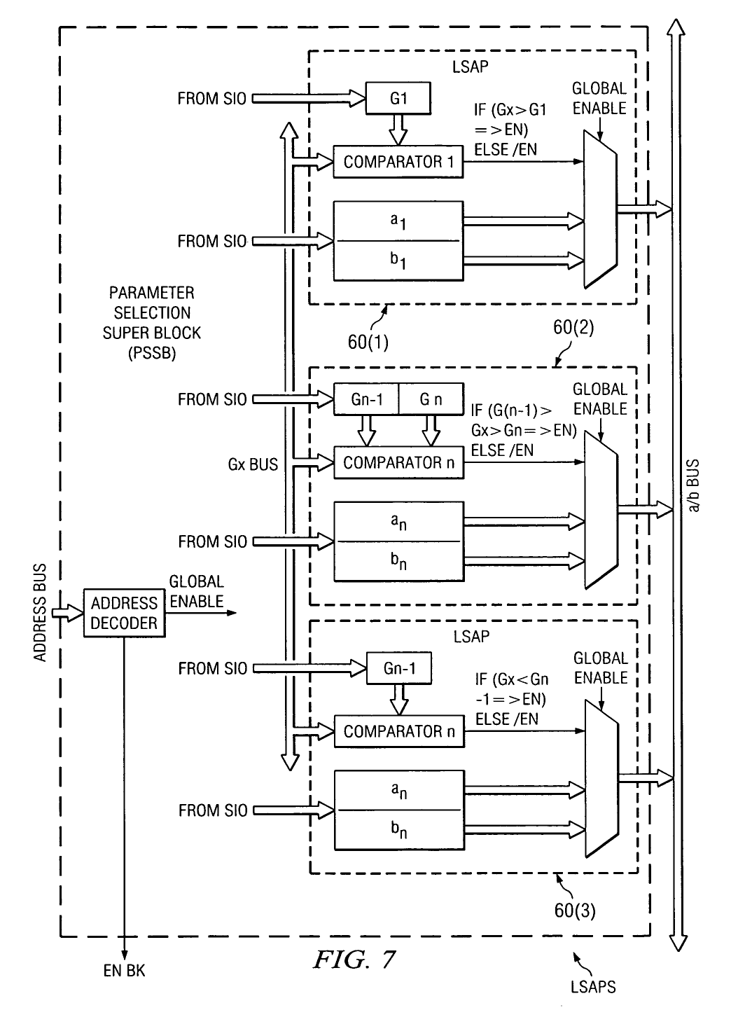

Reference is now made to FIG. 7 wherein there is shown a block diagram of a linear segment approximation parameter super (LSAPS) block. The linear segment approximation super block comprises a cluster of linear segment approximation parameter (LSAP) blocks 60 (not all shown in the figure). The super block performs the function of direct synthesis of appropriate gain or current control curves. Each LSAP block 60 can take on a number of different forms, but each block 60 is responsible for the piecewise approximation of an a/b parameter selection. In order to achieve full piecewise approximation, three types of LSAP blocks 60 are deployed.

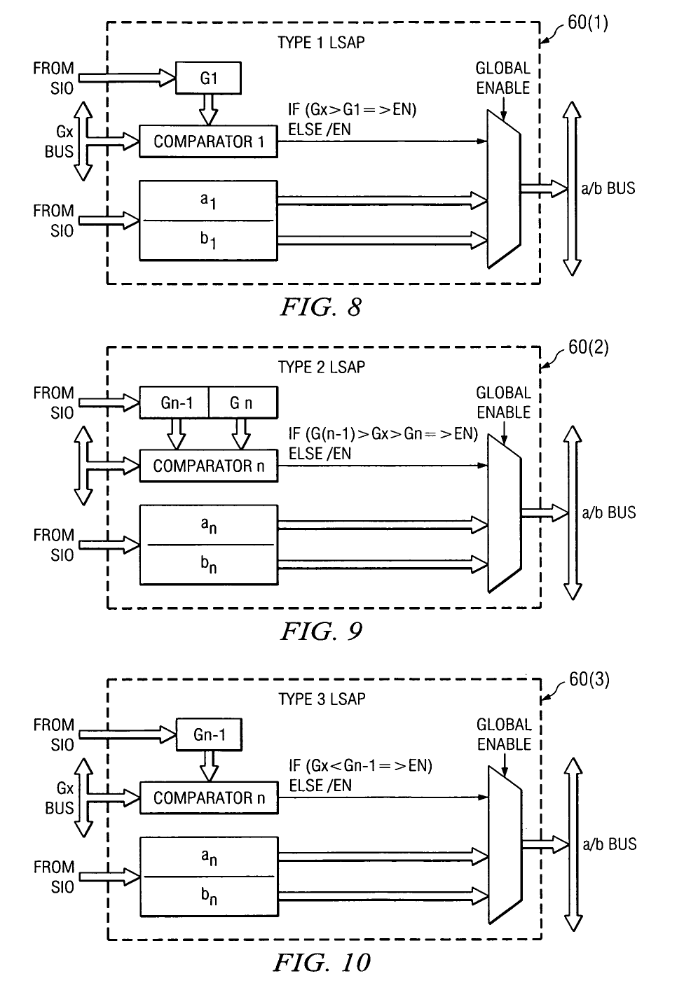

Reference is now made to FIG. 8 wherein there is shown a block diagram of a first type of LSAP block 60(1). Register G1 is a 10-bit register that is accessible through the SIO bus and operable to store a reference gain value. Register “a” is a 10-bit register that is accessible through the SIO bus and operable to store a direction coefficient of the a/b parameters for a linear segment. Register “b” is a 15-bit register that is accessible through the SIO bus and operable to store an offset coefficient of the a/b parameters for a linear segment. The comparison operation compares the current gain value on the Gx bus against the G1 reference. If Gx>G1, then the stored a/b parameters in the “a” and “b” registers are passed by the block 60(1) onto the a/b bus.

Reference is now made to FIG. 9 wherein there is shown a block diagram of a second type of LSAP block 60(2). Registers Gn-1 and Gn are each 10-bit registers that are accessible through the SIO bus and operable to store reference gain values. Register “a” is a 10-bit register that is accessible through the SIO bus and operable to store a direction coefficient of the a/b parameters for a linear segment. Register “b” is a 15-bit register that is accessible through the SIO bus and operable to store an offset coefficient of the a/b parameters for a linear segment. The comparison operation compares the current gain value on the Gx bus against both of the Gn-1 and Gn references. If Gn-1>Gx>Gn, then the stored a/b parameters in the “a” and “b” registers are passed by the block 60(2) onto the a/b bus.

Reference is now made to FIG. 10 wherein there is shown a block diagram of a third type of LSAP block 60(3). Register Gn-1 is a 10-bit register that is accessible through the SIO bus and operable to store a reference gain value. Register “a” is a 10-bit register that is accessible through the SIO bus and operable to store a direction coefficient of the a/b parameters for a linear segment. Register “b” is a 15-bit register that is accessible through the SIO bus and operable to store an offset coefficient of the a/b parameters for a linear segment. The comparison operation compares the current gain value on the Gx bus against the Gn-1 reference. If Gx<Gn-1, then the stored a/b parameters in the “a” and “b” registers are passed by the block 60(3) onto the a/b bus.

It will be noted that the LSAP blocks 60 have a similar configuration. The basic difference among these blocks 60 is in the logic IF clause condition type and in number of reference G registers.

Reference is now once again made to FIG. 7. In a specific exemplary implementation based on six (nₘₐₓ=6) piecewise approximation LSAP blocks 60 (not all shown in the figure), the linear segment approximation parameter super block (LSAP) comprises one first type LSAP block 60(1), one third type LSAP block 60(3), and four second type LSAP blocks 60(2) (only one shown). The linear segment approximation parameter super LSAPS block further includes an address decoder coupled to the address bus. Only one linear segment approximation parameter super block (LSAP) is activated at a time. The address decoder receives address data output from the sequencer block (SQ), decodes the address data and generates an enable (GLOBAL ENABLE) signal for application to each of the included LSAP blocks 60 if the super block (LSAPS) has been addressed and thus selected for operation. The address decoder further generates, based on decoding the received address data, the enable (EN) signal which is used to enable a corresponding block in the set of k PDM DAC (PDAC) blocks comprising the digital-to-analog converters (DAC) 40.

Reference is now once again made to FIG. 2. As discussed above, the arithmetic logic unit (ALU) performs a simple operation of multiplication and subtraction (see, equation 1). This mathematical operation results in the generation of a monotonically declining curve. By changing the inversion bit on the PDM DAC at the output, the curve sign will be changed resulting in a monotonically rising curve. The coefficient “b” is a positive value stored in a 15-bit register. The coefficient “a” is stored in a 10-bit register and is scaled in a way to produce an equivalent positive multiplication coefficient in a range that covers between 0 and 30.69 in 0.03 increment steps. The output result Ydac on the Ydac bus is a 10-bit value.

The ALU includes two control signals. The first control signal is the OUT DATA READY signal. This signal is generated when data is loaded in the PDAC buffer. The second control signal is the READY signal. This signal enables or disables the ALU. The READY signal is generated only if the latest REG contents in the PDMD block are different from the previously loaded contents.

The computation time for the ALU is 53.3 us. Thus, all PDM DAC blocks are updated within 53.3 us immediately after completion of a pulse counting process in the PDMD block. Thus, an overall duration of counting and computation process occurs within 106.6 us. In an implementation, five DAC blocks and a temperature compensation block have to be supported. The controlled blocks and parameters are VGA 22 current and gain, VGA 20 gain, PPA current, modulator current and temperature compensation variation. Thus, the computation time for each block is 53.3/6=8.88 us.

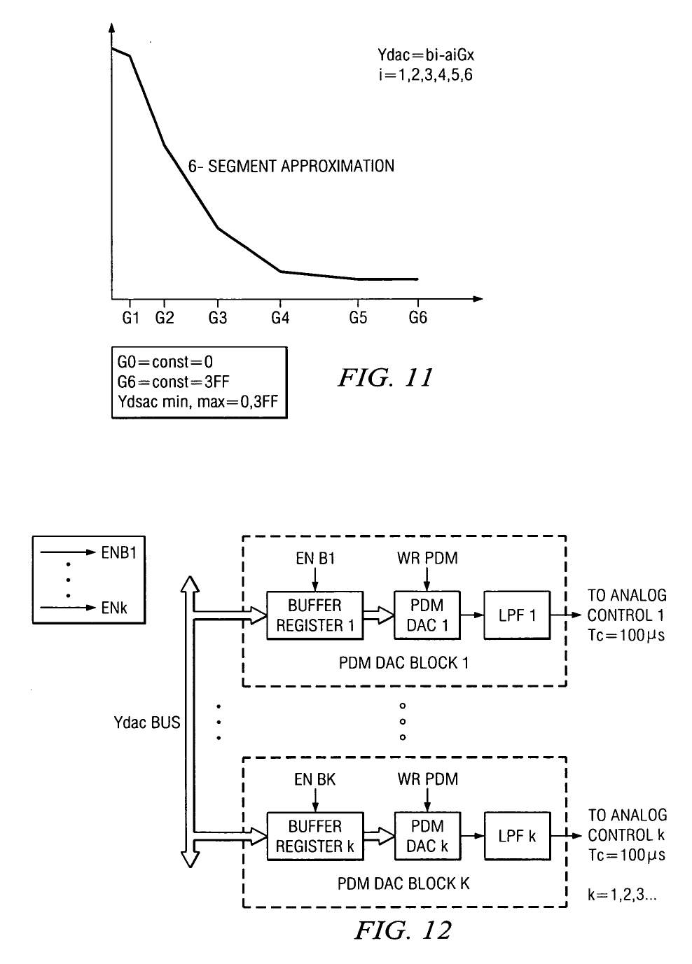

Reference is now made to FIG. 11 wherein there is shown a synthesis of six segments which are piecewise approximated for a hypothetical control current back-off curve. Each segment is generated by a different LSAP block 60 with the nature of the segment being defined by the stored a/b parameters.

Turning next to the sequencer block (SQ) as shown in FIG. 2, it will be remembered that the purpose of the sequencer block is to sequentially (one at the time) enable linear segment approximation parameter super blocks (LSAPS) by generating an appropriate address word for each LSAPS. Once the last address in the sequence is generated, the OUT DATA READY signal is generated by ALU and applied back to the sequencer block (SQ). Responsive thereto, the sequencer block (SQ) generates the WR PDM signal which is applied to the PDAC blocks. Responsive to this signal, the PDAC blocks allow for the writing of a new set of data from their buffer registers into their PDM DAC registers (for the purpose of generating an analog output).

The READY signal received by the sequencer block (SQ) comes from the PDMD block. This signal on the output of the PDMD block is generated when the current content loaded on a register therein differs from previously loaded content. The active READY signal then triggers operation of the sequencer block (SQ) to count its cycle. When the count is completed, the sequencer block (SQ) resets the READY signal.

Reference is now made to FIG. 12 wherein there is shown a block diagram of a PDM DAC (PDAC) block. The PDAC block includes a 10-bit data buffer having an input connected to the Ydac bus. The data buffer includes an input receiving the enable (EN) signal. The PDAC block further includes a 10-bit PDM DAC having an input connected to an output of the data buffer. The PDM DAC includes an input receiving the WRITE TO PDM signal. The PDAC block further includes an integrator or low-pass filter LPF having an input connected to an output (analog) of the PDM DAC. The PDAC block functions, through the data buffer, to latch output ALU computation data from the Ydac bus when the data buffer is enabled by the enable (EN) signal output from the LSAPS. In response to receipt of an active WRITE TO PDM signal (issued once the data buffers of all the included PDAC blocks are loaded with ALU output data when the sequencer block (SQ) finishes it cycle), the buffered data is latched on in the PDM DAC. The integrator (low-pass filter) then provides the analog output (PDM signal DC component).

In this regard, it will be noted that the process of decoding a digital PDM signal into an analog signal is simple requiring only that the signal be passed through an analog low-pass filter (integrator). This works because the function of a low-pass filter is essentially to average the signal. The density of pulses is measured by the average amplitude of those pulses over time, thus a low pass filter (integrator) is the only step required in the digital to analog conversion process. The PDM integration constant may be 100 us. However, due to implementation variations, the low pass filter (integrator) should support a programmable time constant of +/−20 us. The output is preferably temperature compensated with a 0.1-1.8V output range. The integrator further preferably support operation at multiple PDM update frequencies, such as both 19.2 or 9.6 MHz.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A transmitter, comprising:
a gain controllable device which processes a transmit signal, the gain controllable device receiving an analog gain control signal which sets a gain of the gain controllable device;
a logic circuit receiving a specification of the analog gain control signal and generating a digital gain control signal based thereon; and
a digital-to-analog converter circuit that converts the digital gain control signal to the analog gain control signal for application to the gain controllable device.

2. The transmitter of claim 1 wherein the gain controllable device is a variable gain amplifier.

3. The transmitter of claim 1 wherein the gain controllable device is a modulator.

4. The transmitter of claim 1 wherein the digital gain control signal generated by the logic circuit comprises a plurality of linear segments which approximate the specification of the analog gain control signal, and the generated analog gain control signal is comprised of a corresponding plurality of analog linear segments.

5. The transmitter of claim 1 wherein the specification of the analog gain control signal is a pulse density modulation (PDM) specification of the analog gain control signal.

6. The transmitter of claim 5 wherein the logic circuit comprises a PDM decoder operating to decode the PDM specification and generate PDM digital data describing the analog gain control signal.

7. The transmitter of claim 6 wherein the logic circuit further comprises a linear segment approximator which receives the PDM digital data describing the analog gain control signal and generates parameters digitally specifying a plurality of connected line segments which approximate the specification of the analog gain control signal.

8. The transmitter of claim 7 wherein the logic circuit further comprises an arithmetic logic unit which arithmetically processes the parameters digitally specifying a plurality of connected linear segments to generate digital data describing the plurality of connected linear segments, wherein the digital-to-analog converter circuit converts the generated digital data to generate the analog gain control signal which is comprised of a corresponding plurality of connected analog linear segments.

9. The transmitter of claim 1 wherein the logic circuit generates a digital piecewise approximation of the analog gain control signal as the digital gain control signal and the digital-to-analog converter circuit converts that digital piecewise approximation into the analog gain control signal which is also a piecewise approximation for application to the gain controllable device.

10. A transmitter, comprising:
a device which processes a transmit signal, the device having a controllable bias and receiving an analog bias control signal which sets a bias of the device;
a logic circuit receiving a specification of the analog bias control signal and generating a digital bias control signal based thereon; and
a digital-to-analog converter circuit that converts the digital bias control signal to the analog bias control signal for application to the device.

11. The transmitter of claim 10 wherein the device whose bias is controllable is a variable gain amplifier.

12. The transmitter of claim 10 wherein the device whose bias is controllable is a power amplifier.

13. The transmitter of claim 10 wherein the device whose bias is controllable is a modulator.

14. The transmitter of claim 10 wherein the digital bias control signal generated by the logic circuit comprises a plurality of linear segments which approximate the specification of the analog bias control signal, and the generated analog bias control signal is comprised of a corresponding plurality of analog linear segments.

15. The transmitter of claim 10 wherein the specification of the analog bias control signal is a pulse density modulation (PDM) specification of the analog bias control signal.

16. The transmitter of claim 15 wherein the logic circuit comprises a PDM decoder operating to decode the PDM specification and generate PDM digital data describing the analog bias control signal.

17. The transmitter of claim 16 wherein the logic circuit further comprises a linear segment approximator which receives the PDM digital data describing the analog bias control signal and generates parameters digitally specifying a plurality of connected line segments which approximate the specification of the analog bias control signal.

18. The transmitter of claim 17 wherein the logic circuit further comprises an arithmetic logic unit which arithmetically processes the parameters digitally specifying a plurality of connected linear segments to generate digital data describing the plurality of connected linear segments, wherein the digital-to-analog converter circuit converts the generated digital data to generate the analog bias control signal which is comprised of a corresponding plurality of connected analog linear segments.

19. The transmitter of claim 10 wherein the logic circuit generates a digital piecewise approximation of the analog bias control signal as the digital bias control signal and the digital-to-analog converter circuit converts that digital piecewise approximation into the analog bias control signal which is also a piecewise approximation for application to the device.

20. A transmitter, comprising:
a modulator for modulating a digital baseband signal for RF transmission, the modulator having a controllable bias and receiving an analog bias control signal which sets a bias of the modulator;
an amplifier for amplifying the RF modulated digital baseband signal, the amplifier having a controllable gain and receiving an analog gain control signal which sets a gain of the amplifier;
a logic circuit receiving a specification of the analog bias control signal and the analog gain control signal, the logic circuit generating a digital bias control signal and a digital gain control signal based thereon;
a first digital-to-analog converter circuit that converts the digital bias control signal to the analog bias control signal for application to the modulator; and
a second digital-to-analog converter circuit that converts the digital gain control signal to the analog gain control signal for application to the amplifier.

21. The transmitter of claim 20 wherein the logic circuit generates a digital piecewise approximation of the analog gain/bias control signal as the digital gain/bias control signal and the digital-to-analog converter circuit converts that digital piecewise approximation into the analog gain/bias control signal which is also a piecewise approximation.

22. The transmitter of claim 20 wherein the digital gain/bias control signal generated by the logic circuit comprises a plurality of linear segments which approximate the specification of the analog gain/bias control signal, and the generated analog gain/bias control signal is comprised of a corresponding plurality of analog linear segments.

23. The transmitter of claim 20 wherein the logic circuit comprises a linear segment approximator which receives digital data describing the analog gain/bias control signal and generates parameters digitally specifying a plurality of connected line segments which approximate the specification of the analog gain/bias control signal.

24. The transmitter of claim 23 wherein the logic circuit further comprises an arithmetic logic unit which arithmetically processes the parameters digitally specifying a plurality of connected linear segments to generate digital data describing the plurality of connected linear segments, wherein the digital-to-analog converter circuit converts the generated digital data to generate the analog gain/bias control signal which is comprised of a corresponding plurality of connected analog linear segments.
